(19) United States
(12) Patent Application Publication
(10) Pub. No.: US 2009/0130842 A1
(43) Pub. Date: May 21, 2009

(54) Method of forming contact hole and method of manufacturing semiconductor memory device using the same

(76) Inventors: Dong-Won Hwang, Suwon-si (KR); Kook-Joo Kim, Seoul (KR); Yang-koo Lee, Gwacheon-si (KR); Hun-Jung Yi, Suwon-si (KR)

Correspondence Address: HARNESS, DICKEY & PIERCE, P.L.C., P.O. BOX 8910, RESTON, VA, 20195, US

(21) Appl. No.: 12/289,035

(22) Filed: Oct. 17, 2008

(30) Foreign Application Priority Data
Oct. 17, 2007 (KR) 10-2007-0104310

(51) Int. Cl. H01L 21/4763; H01L 21/302

(52) U.S. Cl. 438/637; 438/750; 438/667; 257/E21.597; 257/E21.158

(57) ABSTRACT

A contact hole forming method and a method of manufacturing semiconductor device using the same may include forming a layer on a substrate; anisotropically etching the layer to form a dummy contact hole exposing the substrate; isotropically etching a sidewall of the dummy contact hole to form a contact hole by alternatively and repeatedly supplying an etching solution including a fluoride salt in a low-polarity organic solvent and deionized water to the dummy contact hole. The methods increase reliability of semiconductor memory devices.

### PRIORITY STATEMENT

This application claims priority under 35 U.S.C. § 119 to Korean Patent Application 10-2007-00104310, filed on Oct. 17, 2007, in the Korean Intellectual Property Office, the contents of which are hereby incorporated by reference in their entirety for all purposes as if fully set forth herein.

### BACKGROUND

1. Technical Field

Example embodiments relate to a method of forming a contact hole and a method of manufacturing semiconductor memory device using the same, for example, a method of forming semiconductor device contact hole in a Capacitor Over Bitline (COB) structure, in which a capacitor is formed after a formation of bit line.

2. Description of the Related Art

An area occupied by a memory cell, referred to as a cell size, has been rapidly reduced recently in attempts to provide high integration semiconductor devices. Such cell size reduction can be obtained by reducing an interval between conductive layers of a unit cell. For example, a cell size in a Dynamic Random Access Memory (DRAM) has been reduced to about 1.5 μm² or below, and an interval of gate electrodes is nearly a minimum feature size that design rules of high integration allow. Accordingly, the size of a contact hole, in which a contact (hereinafter, referred to as ‘bit line contact electrode’ or ‘direct contact (DC) electrode’) if formed between a bit line and a drain area, or a contact (hereinafter, referred to as ‘storage node contact electrode’ or ‘buried contact (BC) electrode) is formed between a storage electrode and a source area, is reduced to around a minimum feature size

A challenge brought by the minimizing tendency is that, an aspect ratio of the contact hole increase when intervals between a contact hole and wiring lines adjacent the contact hole are reduced, and it becomes more and more difficult to fabricate a contact hole in a highly integrated semiconductor memory device employing a multilayer wiring structure. In particular, it is difficult to perform a photolithography process by using only a general photoresist pattern.

Another challenge brought by the minimizing tendency is that, in the COB structure, a storage node contact electrode that connects a storage electrode of capacitor to an active area of a semiconductor substrate must be formed between bit lines. But under the design rule of 0.2 μm or below, a short between the storage node contact electrode and the bit line is likely and/or inevitable when forming the storage node contact electrode in a contact plug type using the design rule of 0.2 μm or below.

To solve this problem, a conventional self aligned contact (SAC) method using insulation layers based on mutually different selection etching ratios has been researched and developed. In the conventional SAC method, a bit line is formed, and then a silicon nitride layer is deposited and patterned on an entire face of the formed object, and a spacer is formed on an upper part and a side face of the bit line. A silicon oxide layer then fills in between the bit lines and is etched anisotropically through a self-alignment method to form a contact hole. Further, to obtain a margin for a storage node contact electrode and a pad electrode, a sidewall of a contact hole is extended isotropically by using an etching solution (LAL) containing HF and NH4F.

The contact hole forming method and a method of manufacturing semiconductor memory device using the same have a low yield of production. When using etching solution containing NH4F to isotropically extend a sidewall of a contact hole in an interlayer insulation film, an etching oxide layer educed and formed on the sidewall of the contact hole causes an etching error. Accordingly, it is difficult to obtain an etching reproducibility in forming the contact hole of a desired and/or predetermined size, which likely results in a decreased production yield.

### SUMMARY

Example embodiments provide a method of forming a contact hole and a semiconductor memory manufacturing method using the same, which may reduce and/or prevent an error due to an etching oxide layer educed from the surface of interlayer insulation film when extending the contact hole, and may increase a production yield.

According to example embodiments, there is provided a method of forming a contact hole that may comprise anisotropically etching a layer (e.g. silicon oxide layer) on a substrate to form a dummy contact hole exposing the substrate; isotropically etching a sidewall of the dummy contact hole to form a contact hole. The isotropically etching of the sidewall may include alternately and repeatedly supplying an etching solution including a fluoride salt in a low-polarity organic solvent and deionized water within the dummy contact hole.

The method may further include drying the dummy contact hole after the deionized water is supplied in the dummy contact hole, and drying the dummy contact hole may include spinning the substrate (e.g. 2000 rpm) or supplying air or N₂ gas to the substrate.

The method may alternatively and repeatedly supply each of the etching solution and the deionized water for a time duration with a range of about 1 through 30 seconds.

The method may further include a spinning scheme in which the etching solution and the deionized water may be dropped onto the substrate. The substrate may be rotated at a speed of 500 rotations per minute.

The fluoride salt may include at least one of NH4HF2, NaF, and KF. The fluoride salt may be molten and may be about 0.001 weight percent through about 2 weight percent in the low-polarity organic solvent.

According to example embodiments, there is provided a method of manufacturing a semiconductor memory device that may comprise forming a transistor on a substrate; forming a first interlayer insulation film having a first contact hole exposing source/drain areas of the transistor; forming a pad electrode within the first contact hole; forming a second interlayer insulation film having a second contact hole exposing the pad electrode; forming a direct contact electrode within the second contact hole, and forming a bit line on the direct contact electrode; forming a third interlayer insulation film at least partially surrounding the bit line; anisotropically removing the second interlayer insulation film and the third interlayer insulation film over a drain area of the transistor to form a dummy contact hole exposing the pad electrode; isotropically etching the second and the third interlayer insulation films on a side wall of the dummy contact hole to form a third contact hole, the isotropically etching of the second and the third interlayer insulation films may include alternately and repeatedly supplying an etching solution that may include a molten fluoride salt in a low-polarity organic solvent; forming a storage node contact electrode in the third contact hole; and forming a capacitor on the storage node contact electrode.

The method may further include drying the dummy contact hole after the deionized water is supplied within the dummy contact hole, and drying the dummy contact hole may include spinning the substrate (e.g. 200 rpm) or supplying air or N₂ gas to the substrate.

The method may alternatively and repeatedly supply each of the etching solution and the deionized water for a time duration with a range of about 1 through 30 seconds.

The method may further include a spinning scheme in which the etching solution and the deionized water may be dropped onto the substrate, which may be rotating at a speed. The substrate may be rotated at a speed of 500 rotations per minute.

The fluoride salt may include at least one of NH4HF2, NaF, and KF. The fluoride salt may be molten and may be about 0.001 weight percent through about 2 weight percent in the low-polarity organic solvent.

As described above, according to example embodiments, etching solution and deionized water may flow alternatively and repeatedly on the substrate surface. The etching solution may etch an interlayer insulation film formed of silicon oxide, and deionized water may remove the etching oxide educed from the surface of interlayer insulation film, thereby an etching process error due to etching oxide layer is reduced and/or prevented, a relatively simpler formation of contact hole of desired and/or predetermined size is provided and so a production yield is increased.

### BRIEF DESCRIPTION OF THE DRAWINGS

The foregoing and other features and advantages of example embodiments will become more clearly understood from the following more detailed description of the accompanying drawings, in which like reference characters refer to the same parts throughout different views. FIGS. 1-13 represent non-limiting, example embodiments as described herein.

FIG. 1 is a plan view showing a portion of DRAM cell for a contact structure of semiconductor memory device according to an example embodiment of the application.

FIGS. 2-9, 14-18 are sectional views of the contact structure, taken along a line I˜I′ shown in FIG. 1, to describe the contact forming method of a semiconductor device according to an example embodiment of the application.

FIG. 10 is a graph illustrating etching depth vs. reaction time of HF and an etching solution with molten fluoride salt.

FIGS. 11A-11C illustrate the obstructing effect of an etching oxide to etching when extending a dummy contact hole.

FIGS. 12A-12D illustrate the extending of a dummy contact hole when alternatively supplying an etching solution with a density of about 1 weight percent and flushing deionized water to a sidewall inside the dummy contact hole for about 7 seconds and repeating four, eight, twelve, and sixteen times, respectively.

FIG. 13 illustrates the extended length of a dummy contact hole vs. the number of times the etching-flushing process was performed.

### DETAILED DESCRIPTION OF EXAMPLE EMBODIMENTS

Example embodiments will now be described more fully with reference to the accompanying drawings, in which example embodiments are shown. Example embodiments may, however, be embodied in many different forms and should not be construed as being limited to the example embodiments set forth herein; rather, example embodiments are provided so that this disclosure will be thorough and complete, and will fully convey the concept of the application to one skilled in the art. In the drawings, the thicknesses of layers and regions are exaggerated for clarity. Like reference numerals in the drawings denote like elements from different views, for example.

While example embodiments of the application are shown by way of example in the drawings and will herein be described in detail, it should be understood, however, that there is no intent to limit example embodiments of the application to the particular forms disclosed. But on the contrary, example embodiments of the application are to cover all modifications, equivalents, and alternatives falling within the scope of the application.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present application. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the application. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the drawings. For example, two drawings shown in succession may in fact be executed substantially concurrently or may sometimes be executed in the reverse order, depending upon the functionality/acts involved.

Also, the use of the words “compound,” “compounds,” or “compound(s),” refer to either a single compound or to a plurality of compounds. These words are used to denote one or more compounds but may also just indicate a single compound.

Unless otherwise defined, all terms (including technical and scientific terms) used herein have the same meaning as commonly understood by one of ordinary skill in the art to which this application belongs. It will be further understood that terms used herein should be interpreted as having a meaning that is consistent with their meaning in the context of this specification and the relevant art and will not be interpreted in an idealized or overly formal sense unless expressly so defined herein.

In the drawings like components having like functions have been provided with like reference symbols and numerals. In addition, in the following description referred to as “existing/adapted/formed ‘on’ a layer or substrate,” it may indicate that any layer exists directly contacted with other layer or substrate or that a third layer is interposed therebetween. Furthermore, interlayer insulation films described in following example embodiments are provided including silicon oxide.

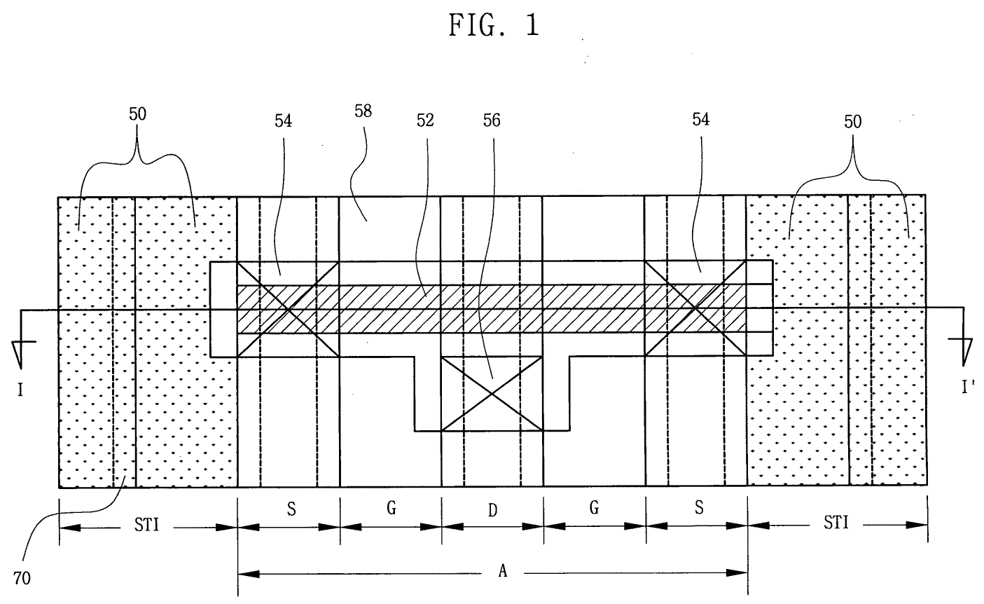

FIG. 1 is a plan view illustrating a portion of DRAM cell for a contact structure of semiconductor memory device according to an example embodiment of the application.

Referring to FIG. 1, a contact structure of semiconductor memory device according to an example embodiment includes a storage node contact electrode 54 and a bit line contact electrode 56. For example, the storage node contact electrode 54 and a bit line contact electrode form a T-shape zone. The storage node contact electrodes 54 may be formed on source areas S. The source areas S may be located at the opposite ends of a unidirectional channel 52, which may be formed from a plurality of gate electrodes and may serve as the horizontal arm of the T-shape zone. The bit line contact electrode 56 may be formed on a common drain area D, which may be at the end of the vertical arm of the T-shape zone.

The T-shape zones may be arranged as an array with equal intervals along the horizontal and vertical direction in an entire cell area on the substrate 60, or may be arrayed, being shifted, in a zigzag manner. Further, according to example embodiments of the application, in a DRAM having a COB structure to be described below, a gate electrode may be electrically connected to a word line 58 of one direction, and a bit line vertically intersected to the word line 58 may be formed.

A method of forming a contact structure with the configuration described above according to example embodiments of the application is described as follows.

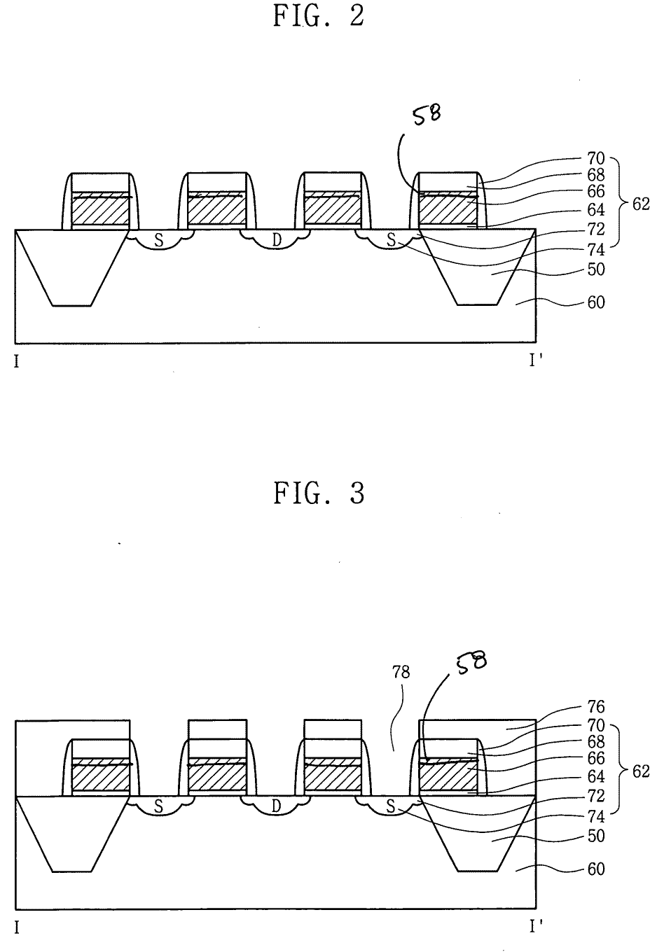

FIGS. 2-9, 14-18 are sectional views of processes taken along a line I˜I′ shown in FIG. 1 to describe a contact forming method of a semiconductor device according to an example embodiment of the application.

As shown in FIG. 2, a shallow trench isolation 50 may be formed to define the active area A on a substrate 60, and a plurality of transistors 62 may be formed in the active area A. Here, the shallow trench isolation 50 may be formed through a trench processor or LOCOS process. To form the plurality of transistors 62, a channel impurity area (not shown) may be formed with a desired and/or a given depth from the surface of semiconductor substrate 60 in which the shallow trench isolation 50 has been formed. A gate insulation layer 64, a gate electrode layer 66, a metal layer 58, and a gate upper insulation layer 68 may then be deposited, on the substrate 60. For example, the gate insulation layer 64 may be a silicon oxide layer formed by a thermal oxidation method; the gate electrode layer 66 may be a polysilicon layer containing conductive impurity; the metal layer 58 may be tungsten silicide or titanium silicide; and the gate upper insulation layer 68 may be a silicon nitride layer or silicon oxide nitride layer. The gate electrode 66 may be formed on an entire face of the substrate 60. The metal layer 58 may also serve as a word line. Next, the stack of layers (58, 64, 66, and 68) may be etched through a general photolithography process, so that a surface of the source/drain areas S/D of substrate 60 may be exposed and gate stacks (58, 64, 66, and 68) may be formed in a gate area (area G of FIG. 1). Using the gate stack as an ion implantation mask, N-type or P-type impurities may be ion-implanted to the substrate 60 to form a first impurity area 72 in the source/drain areas S/D.

Further, a silicon nitride layer with a given thickness may be deposited on the substrate 60, and may be etched to expose the surface of source/drain areas S/D through a dry etching method with a prominent anisotropy etching characteristic, thus forming a first spacer 70 on a sidewall of the gate stack 62. Using the first spacer 70 as an ion implantation mask through a self-alignment method, P-type or N-type conductive impurities may further be ion implanted in the source/drain areas S/D, thereby forming a second impurity area 74.

Referring to FIG. 3, a first interlayer insulation film 76 (e.g. silicon oxide) may be formed to bury at least a portion of the gate stack (58, 64, 66, 68 and 70) on the semiconductor substrate 60 after formation of the second impurity area 74. Using a general photolithography process, a first contact hole (pad contact hole) 78 may be formed by selectively removing the first interlayer insulation film 76 over the second impurity area 74. An additional chemical mechanical planarization process may be performed before the photolithography process to planarize the first interlayer insulation film 76.

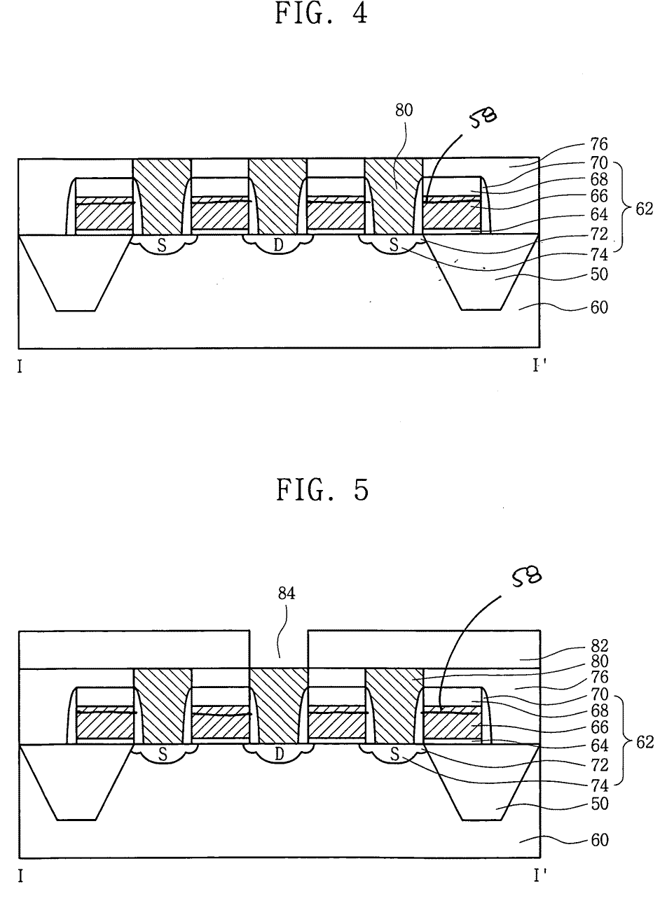

As shown in FIG. 4, a pad electrode 80 may be formed within the first contact hole 78. The pad electrode 80 may be formed by first depositing a polysilicon layer doped with conductive impurity on an entire face of the substrate 60 to fill the contact hole 78, and then using a chemical mechanical polishing (CMP) method to remove the polysilicon layer and to expose the first interlayer insulation film 76. Therefore, the pad electrode 80 may be formed in each end part of the T-shape shown in FIG. 1, and may be electrically coupled to the surface of substrate 60 of the source/drain areas.

Although not shown in the drawing, the pad electrode 80 may alternatively have an upper/lower stack structure including a first polysilicon layer and a second polysilicon layer. To form the upper/lower stack structure, the first polysilicon layer containing conductive impurity may be formed on an entire face of the substrate 60 after formation of the second impurity area 74, but before the deposition of the first interlayer insulation film 76, so that the doped polysilicon may directly cover the second impurity area 74. Then, a CMP method may be performed to planarize the substrate 60 and expose the gate upper insulation layer 68 but keep the doped polysilicon that may cover the second impurity area 74. A first interlayer insulation film 76 may be formed on an entire face of the substrate 60, and may then be selectively removed to form a first contact hole 78 and expose the first polysilicon layer. Further, the second polysilicon layer may be formed on an entire face of the substrate 60 and may fill the first contact hole 48. Lastly, the second polysilicon layer may be selectively removed to expose the first interlayer insulation film 76. Thus, the pad electrode 80 may be formed with the upper/lower stack structure and electrically coupled to the source/drain areas S/D.

Referring to FIG. 5, a second interlayer insulation film 82 having a given thickness may be formed on an entire face of substrate 60 after formation of the pad electrode 80. A second contact hole 84 may be formed by selectively removing the portion of the second interlayer insulation film 82 over the drain area D by an anisotropic dry etching method. The second interlayer insulation film 82 may be BPSG (Boron Phosphorus Silicate Glass) silicon oxide, with a thickness about 2000 Å to about 5000 Å

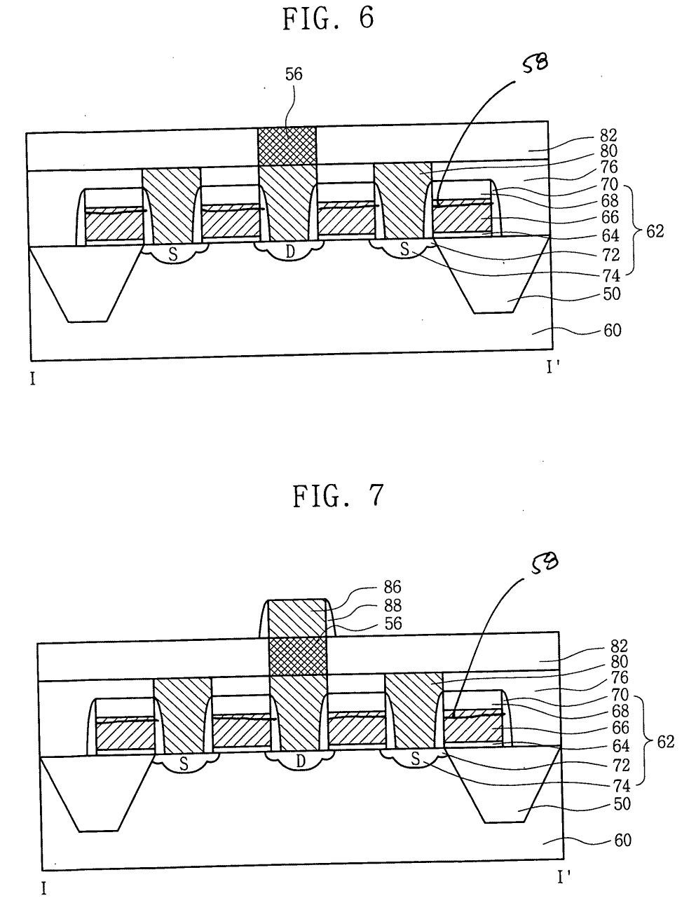

Referring to FIG. 6, a bit line contact electrode 56 may be formed within the second contact hole 84. The bit line contact electrode 56 may be formed by forming a polysilicon layer containing conductive impurity or a conductive metal layer (e.g. titanium, titanium silicide, tungsten, tungsten silicide) on the substrate 60, and then removing the portion of the conductive metal layer or polysilicon layer over the second interlayer insulation film 82 to expose the second interlayer insulation film 82.

Referring to FIG. 7, a bit line 86 may be formed on the bit line contact electrode 56, and a second spacer 88 may be formed on a sidewall of the bit line 86. To form the bit line 86, a metal layer or polysilicon layer doped with conductive impurity may first be deposited on the substrate 60, and then the metal layer or polysilicon layer may be etched by an anisotropy dry etching method using a pattern mask layer that shields the metal layer or polysilicon layer to form the bit line 86 over the bit line contact electrode 56. Thus, the bit line 86 and the bit line contact electrode 56 may be electrically connected to the pad electrode 80. To form the second spacer 88, a silicon nitride layer with a given thickness may be deposited on the substrate 60 after forming the bit line 86. Through a dry etching method having a prominent anisotropy etching characteristic, the silicon nitride layer may be etched until an upper surface of the bit line 86 is exposed, thus forming the second spacer 88 on the sidewall of the bit line 86. Alternatively, when the second interlayer insulation film 82 does not exist, or is thinner than the given thickness, the bit line contact electrode 56 and the bit line 86 may be formed together in one processing step.

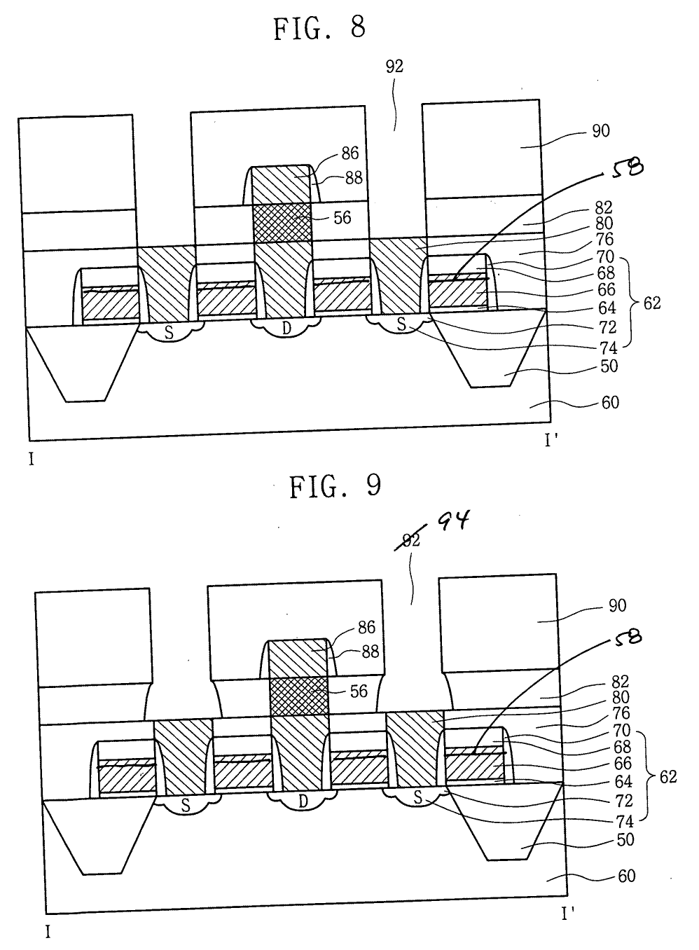

As shown in FIGS. 8, 9, and 14, a third interlayer insulation film 90 may be formed on an entire face of a substrate 60 on which the bit line 86 and the second spacer 88 have been formed. A dummy contact hole 92 may be formed to expose the pad electrode 80. The dummy contact hole 92 may then be expanded to a third contact hole 94, wherein a storage contact electrode 54 may be finally formed.

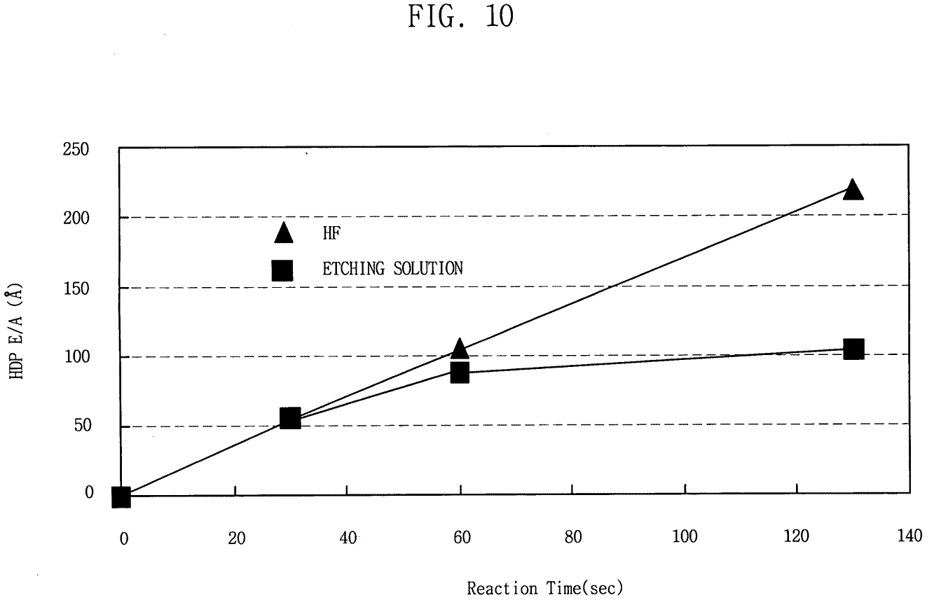

Referring to FIG. 8, the third interlayer insulation film 90 (e.g. high density plasma silicon oxide) may be thick enough (e.g. about 5000 Å or more) to reduce a step coverage, since error may be caused in forming a third contact hole (94 of FIG. 9) in a subsequent process when the step coverage is generated by the bit line 86 protruded from the surface of substrate 60. When the step coverage of the third interlayer insulation film 90 cannot be reduced, a CMP process may be added to planarize the third interlayer insulation film 90.

The dummy contact hole 92 may be formed by sequentially and anisotropically removing the third and second interlayer insulation films 90 and 82 formed on the source area S through a dry etching method. In the dry etching method, a patterned photoresist layer may be used as an etching mask to expose the third interlayer insulation film 90 formed on the source area S, and the dummy contact hole 92 having a dominant aspect ratio may be formed by concentrating reaction gas having a selectivity to the third and second interlayer insulation films 90 and 82. As a depth of dummy contact hole 92 increases, a length of a storage node contact electrode 54 subsequently formed in the dummy contact hole increases. Further, a contact area margin between the storage node contact electrode 54 and the pad electrode 80 may be reduced. Therefore, the contact area margin between the storage node contact electrode 54 and the pad electrode 80 is increased by extending the size of dummy contact hole 92 according to example embodiments of the present application.

Referring to FIG. 9, the size of dummy contact hole 92 may be expanded through an isotropic wet etching method with a selectivity of the third and second interlayer insulation films 90 and 82, thus forming the third contact hole 94. The wet etching method may be classified as a dip method that places the substrate 60 into an etching tub and a spinning method that supplies etching solution to the substrate 60 and simultaneously spins the substrate 60 (e.g. at about 500 rpm). The dip method is performed in a batch process of etching a plurality of substrates 60, and may be an etching technique to thoroughly etch the desired area in patterned layers and/or entirely removed undesired pollution materials on the plurality of substrates 60. Meanwhile, the spinning method is to produce a micro pattern or micro etch on separate sheets of the substrates 60. Therefore, according to an example embodiment of the present application, by taking advantage of the spinning scheme in the wet etching method, a sidewall of dummy contact hole 92 may be isotropically extended by a micro level in the contact hole forming method.

To use the spinning scheme in the wet etching method to form the third contact hole 94, etching solution and deionized water may alternately be supplied to the surface of substrate 60. The etching solution may be a mixture solution containing fluoride salt and low-polarity organic solvent. The fluoride salt may contain NH₄HF₂, NaF or KF. Also, low-polarity organic solvent may contain dimethylformamide, dimethyl sulfoxide, acetonitrile, tetrahydrofuram and methyl ethyl ketone. For example, the fluoride salt molten in low-polarity organic solvent may have a density of about 0.001 weight percent to about 2 weight percent. The etching solution may have an etching characteristic of about 1:1.2 for a high density plasma silicon oxide layer:BPSG silicon oxide layer. Accordingly, the second interlayer insulation film 82 may be etched faster than the third interlayer insulation film 90, thus forming the third contact hole 94 having a pot shape.

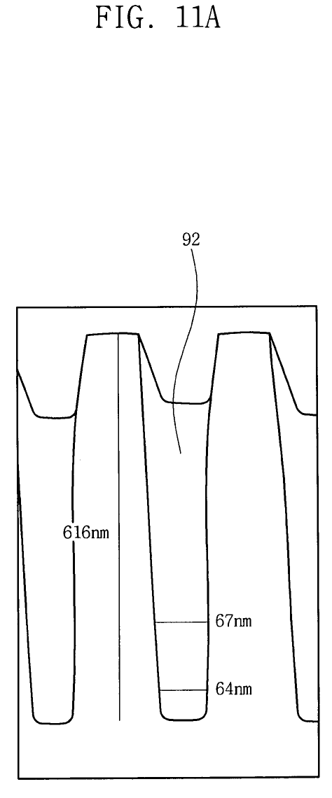

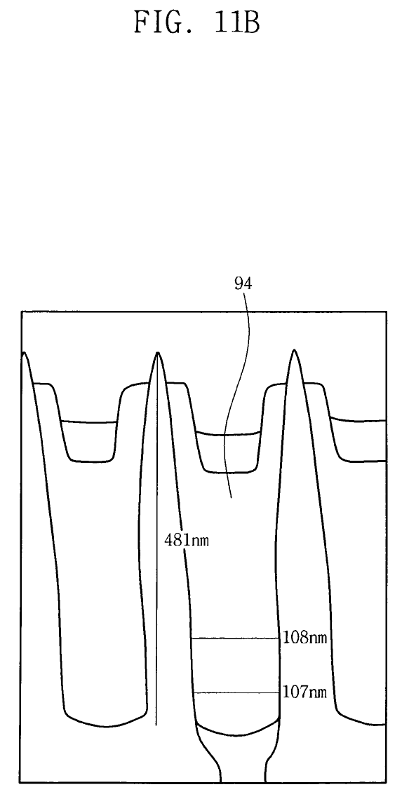

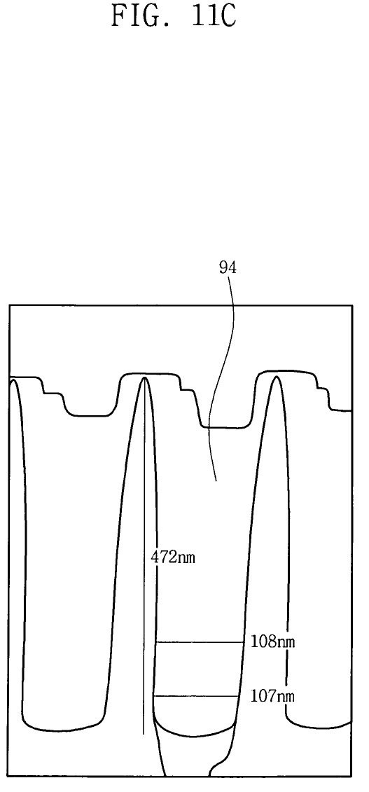

FIG. 10 illustrates etching depth vs. reaction time of HF and the etching solution with molten fluoride salt. Compared to the etching rate of HF in forming the third contact hole 94, the etching rate of the etching solution with molten fluoride salt slows down as the reaction time lapses and after a time duration stops etching. When the etching time lapses, a large amount of etching oxide may be generated inside the dummy contact hole 92 and may not be efficiently removed out of the dummy contact hole 92, therefore, the extending of the third contact hole 94 may be obstructed. FIGS. 11A-11C show the effect of this obstruction in an example experiment. For example, when two dummy contact holes 92 having a similar diameter of about 67 nm (see FIG. 11A) are spun at a same or similar speed and are exposed to etching solutions of the same or similar mixing rate for 3 minutes and 6 minutes, respectively, the third contact holes 94 with diameters of about 107 nm through 108 nm size are respectively formed, as shown in FIGS. 11B and 11C. In addition, because the etching solution flows on the surface of substrate 60 and thus the third interlayer insulation film 90 is removed in proportionate to a flow speed of the etching solution, the thickness of third interlayer insulation film 90 becomes thinner after etching, as shown in FIGS. 11A-11C. Meantime, a sidewall of the second and third interlayer insulation films 82 and 90 may be etched in a state that a flow of etching solution supplied to the inside of dummy contact hole 92 is almost negligible. Accordingly, the etching oxide layer may be formed as a passive layer on the surface of the second and third interlayer insulation films 82 and 90 in the inside or sidewall of dummy contact hole 92.

The etching oxide layer inside or on the sidewall of the dummy contact hole 92 may be removed by flushing deionized water into the dummy contact hole 92 followed by a drying process to remove the deionized water from the substrate 60. The etching oxide layer may mainly be ammonium and organic matters having a dominant hydrophilic property, thus may be removed easily by flushing the deionized water into the dummy contact hole 92. The deionized water may then be removed from the substrate and the dummy contact hole 92. The etching solution formed of mixed solution contains strong acid material having a dominant hydrophilic property. As such, if water were not removed, etching solution would be diluted and effective etching would not be guaranteed. Therefore, a dry process of drying the substrate 60 after a supply of deionized water may be added. To remove the deionized water, the substrate 60 may be spun at a speed of about 200 rpm by a spinner or may be dried by air of N₂ gas having a desired and/or predetermined temperature, which is provided with a desired and/or predetermined flow speed.

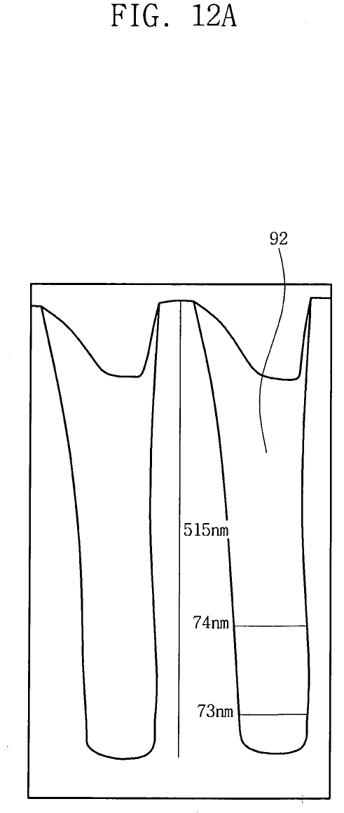

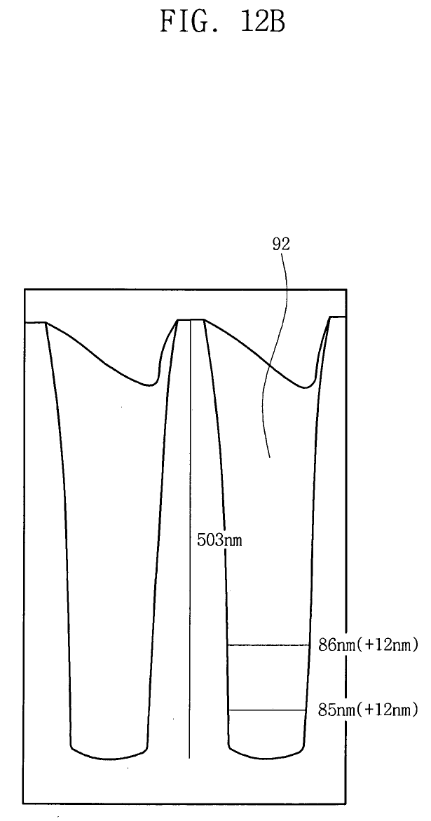

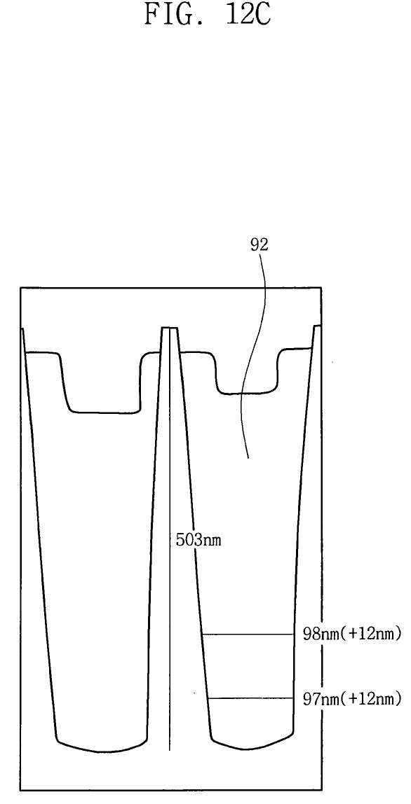

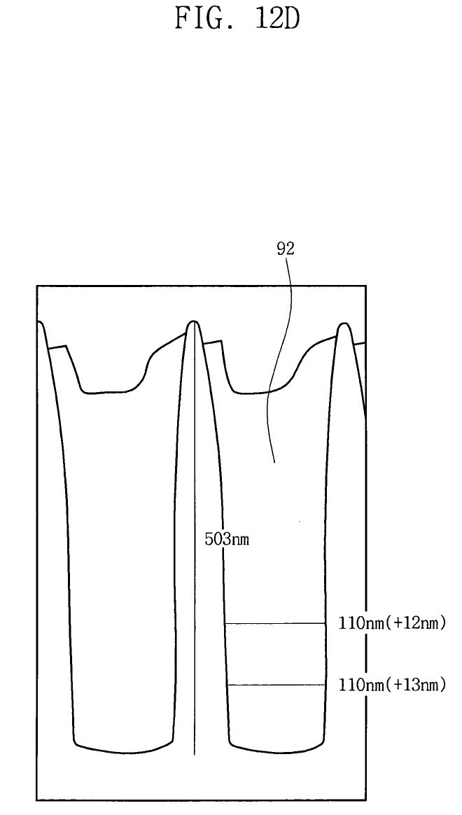

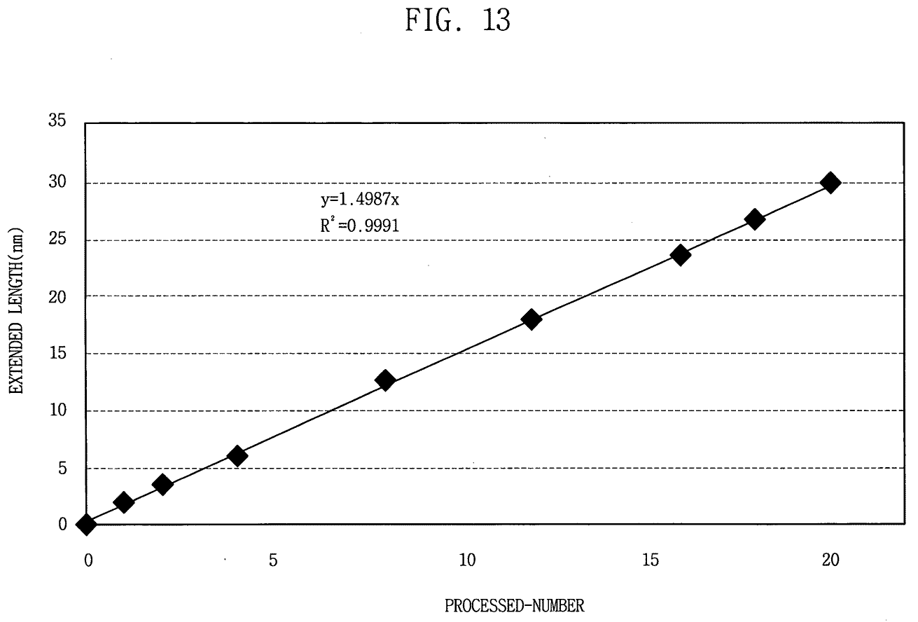

For example, etching solution and deionized water may be supplied to the surface of substrate 60 undergoing an etching process of wet etching method in each 1 to 30 second period. For example, etching solution and deionized water may alternatively flow on the surface of substrate 60 for about 7 seconds and may be repeated four, eight, twelve and sixteen times. The dummy contact hole 92 is extended as shown in FIGS. 12A to 12D. Here the fluoride salt of etching solution has a density of about 1 weight percent. Whenever etching solution and deionized water are alternately supplied four times, a depth of dummy contact hole 92 is relatively unchanged. However, a diameter of dummy contact hole 92 is increased about 12 nm during each of the four cycles as shown in the example of FIGS. 12A-12D.

FIG. 13 illustrates an extended length of a dummy contact hole 92 with respect to the number of cycles of the etching-flushing process to a substrate 60. The horizontal axis indicates the number of times the etching-flushing process is applied, and the vertical axis indicates the extended length of the dummy contact hole 92. The etching solution having a density of about 0.5 weight percent of fluoride salt, and deionized water are alternatively supplied to the surface of the substrate 60 about every 7 seconds for one time, two times, four times, eight times, twelve times, sixteen times, eighteen times, and twenty times, respectively. The diameter of the dummy contact hole 92 extends about 6 nm for every four times the etching-flushing process is applied.

Accordingly, in a contact hole forming method according to an example embodiment of the present application, an etching solution and deionized water may be alternately and repeatedly supplied to a substrate 60 to etch a dummy contact hole 92 formed in a second and a third interlayer insulation film 82 and 90, and to remove an etching oxide layer on a sidewall of the dummy contact hole 92, thereby easily forming the third contact hole 94 of a predetermined size and thus increasing a production yield.

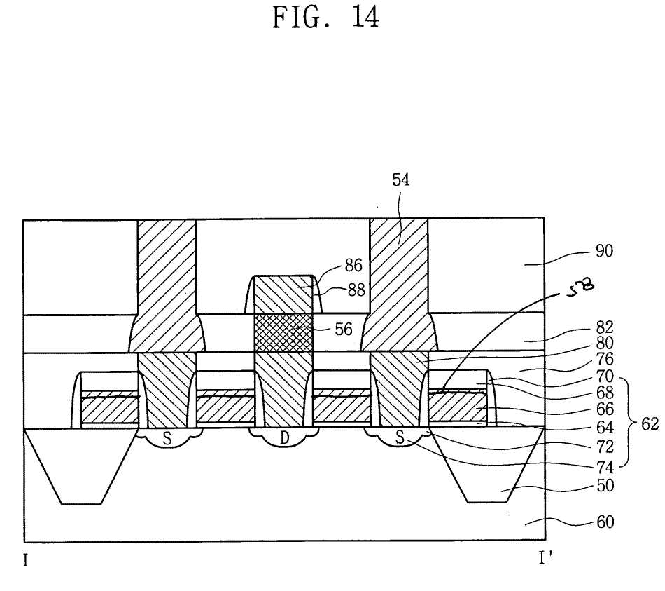

Referring to FIG. 14, a storage node contact electrode 54 may be formed inside the third contact hole 94. The storage node contact electrode 54 may be formed by depositing a metal layer or polysilicon layer doped with conductive impurity on the substrate 60, and by removing the polysilicon layer or metal layer to planarize and to expose the third interlayer insulation film 90. For example, the polysilicon layer or metal layer may be formed through a CVD method having a dominant filling characteristic for the third contact hole 94.

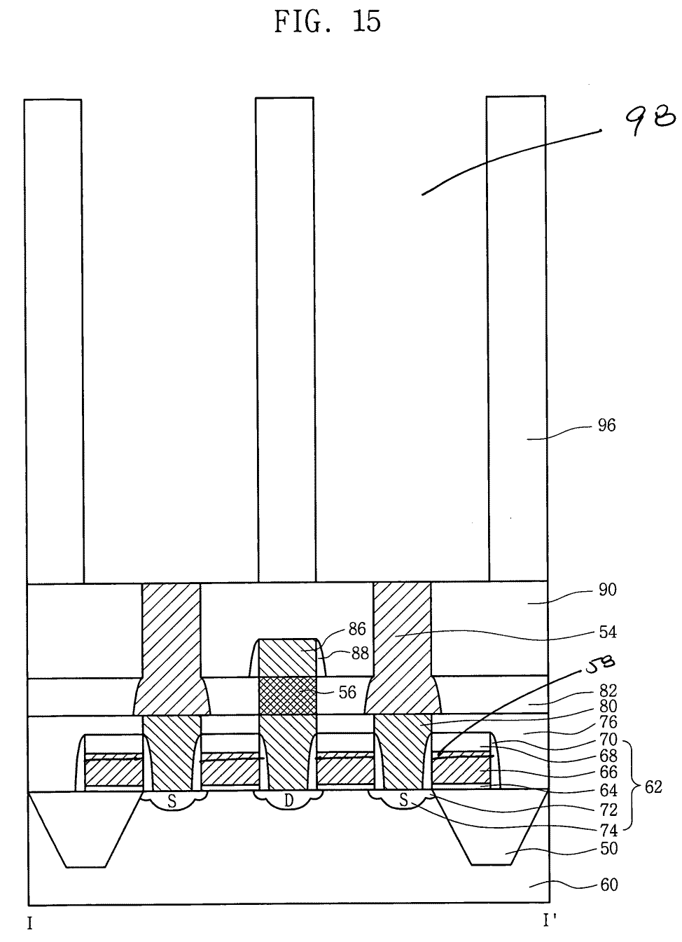

Referring to FIG. 15, a mold oxide layer 96 may be formed on the substrate 60, and the portion of mold oxide layer 96 over the storage node contact electrode 54 may be removed to form a trench 98 and to expose the storage node contact electrode 54. The mold oxide layer 96 may be formed containing a high density plasma silicon oxide film or thermal oxide silicon oxide film etc.

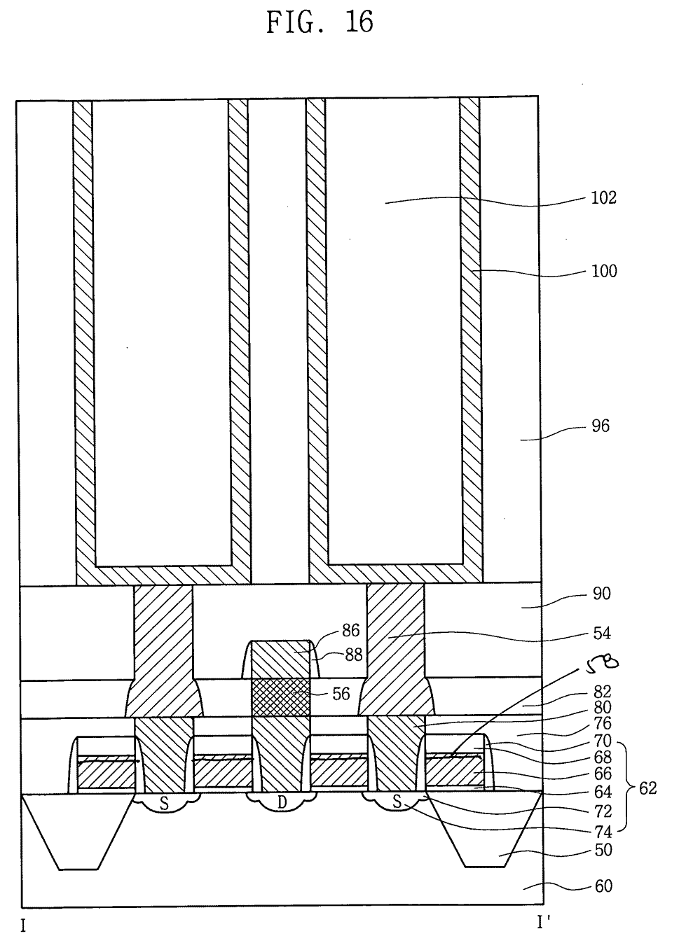

Referring to FIG. 16, a cylindrical storage electrode 100 of a given thickness may be formed inside the trench 98. The storage electrode 100 may be formed as follows. First, a polyslilicon layer doped with conductive impurity or a conductive metal layer may be deposited to a desired and/or given thickness on an entire face of the substrate 60 including the trench 98. Then, a sacrificial oxide layer 102 may be deposited to fill the trench 98. Then, the substrate 60 may be planarized by a CMP process or etch back process to expose the mold oxide layer 96. Therefore, a storage electrode 100 having a desired and/or given thickness may be formed inside the trench 98.

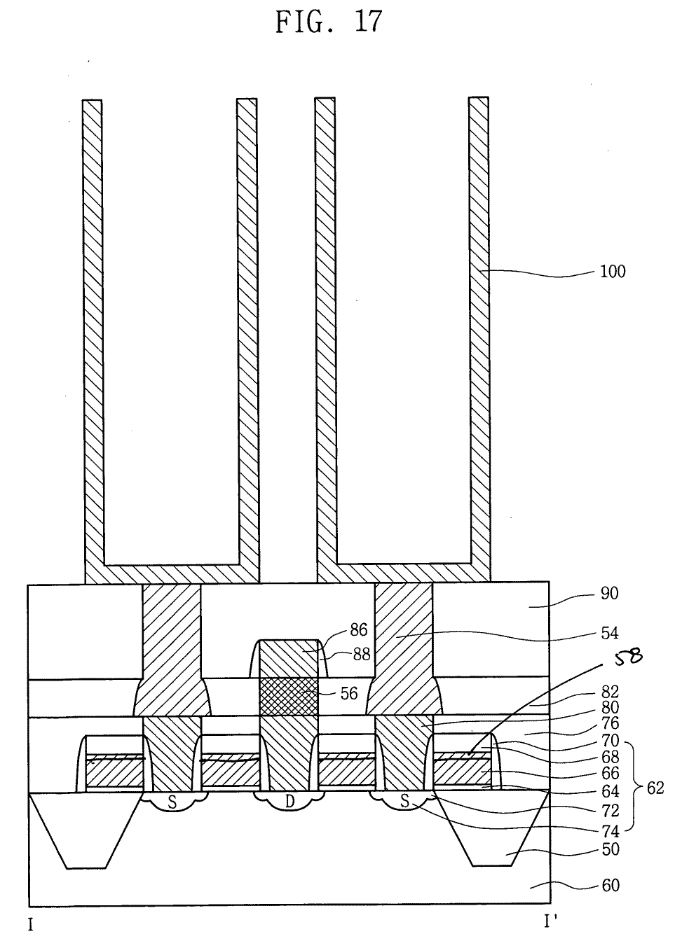

Referring to FIG. 17, the mold oxide layer 96 and the sacrifice oxide layer 102 may be removed through wet etching method. The mold oxide layer 96 and the sacrifice oxide layer 102 may be eliminated by the dip scheme or spinning scheme in a buffer solution. The buffer solution may be an LAL solution, which is a mixture of HF:NH4F in a rate about 1:5 to about 1:10.

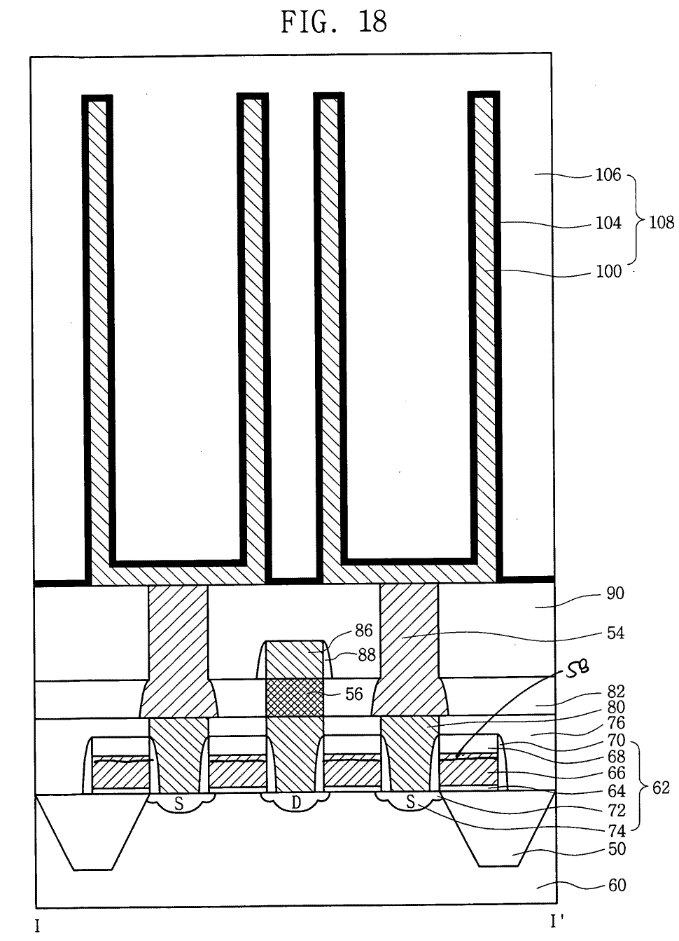

Referring to FIG. 18, a storage capacitor 108 may be formed by sequentially forming a dielectric layer 104 and a plate electrode 106 on the storage electrode 100. For example, the dielectric layer 104 may be formed including at least one of aluminum oxide and hafnium oxide with a thickness of about 20 Å to about 50 Å. Like the storage electrode 100, the plate electrode 106 may be formed including a conductive metal layer or polysilicon layer doped with conductive impurity.

Accordingly, in a contact hole forming method and a semiconductor memory device manufacturing method employing the same according to an example embodiment of the present application, an etching solution may be supplied to the substrate to etch a dummy contact hole 92 formed in a second and third interlayer insulation films 82 and 90. The substrate 60 may then be flushed by deionized water to remove an etching oxide inside and on a sidewall of the dummy contact hole 93. The etching and flushing may be performed alternatively and repeatedly, thereby reducing and/or preventing error of etching process due to the etching oxide layer, making easier the formation of a third contact hole 94 to a predetermined size, and thus increasing a production yield.

It is apparent to one skill in the art that modifications and variations may be made in the present application without deviating from the spirit or scope of the application. Thus, it is intended that the present application covers any of such modifications and variations this application may provide within the scope of the appended claims and their equivalents. Accordingly, these and other changes and modifications are seen to be within the true spirit and scope of the application.

What is claimed is:

1. A method of forming a contact hole, comprising:
anisotropically etching a layer on a substrate to form a dummy contact hole exposing the substrate; and
isotropically etching a sidewall of the dummy contact hole to form a contact hole, the isotropically etching of the sidewall including alternatively and repeatedly supplying an etching solution including a fluoride salt in a low-polarity organic solvent and deionized water within the dummy contact hole.

2. The method of claim 1, wherein the isotropically etching further includes drying the dummy contact hole after the deionized water is supplied within the dummy contact hole.

3. The method of claim 1, wherein the isotropically etching alternatively and repeatedly supplies each of the etching solution and the deionized water for a time duration with a range of about 1 through 30 seconds.

4. The method of claim 1, wherein the isotropically etching further includes a spinning scheme in which the etching solution and the deionized water are dropped onto the substrate, which is rotating at a speed.

5. The method of claim 4, wherein the substrate is rotated at a speed of 500 rotations per minute.

6. The method of claim 1, wherein the fluoride salt includes at least one of NH₄HF₂, NaF, and KF.

7. The method of claim 6, wherein the fluoride salt is molten and is about 0.001 weight percent through about 2 weight percent in the low-polarity organic solvent.

8. A method of manufacturing a semiconductor memory device, the method comprising:
forming a transistor on a substrate;
forming a first interlayer insulation film having a first contact hole exposing source/drain areas of the transistor;
forming a pad electrode within the first contact hole;
forming a second interlayer insulation film having a second contact hole exposing the pad electrode;
forming a direct contact electrode within the second contact hole;
forming a bit line on the direct contact electrode;
forming a third interlayer insulation film at least partially surrounding the bit line;
forming a contact hole in the second interlayer insulation film and the third interlayer insulation film over a drain area of the transistor exposing the pad electrode, using the method of claim 1;
forming a storage node contact electrode within the third contact hole; and
forming a capacitor on the storage node contact electrode.

9. The method of claim 8, wherein the isotropically etching includes drying the dummy contact hole after the deionized water is supplied within the dummy contact hole.

10. The method of claim 8, wherein the isotropically etching alternatively and repeatedly supplies each of the etching solution and deionized water for a time duration within a range of about 1 through 30 seconds.

11. The method of claim 8, wherein the isotropically etching further includes a spinning scheme in which the etching solution and the deionized water are dropped onto the substrate, which is rotating at a speed.

12. The method of claim 11, wherein the substrate is rotated at a speed of 500 rotations per minute.

13. The method of claim 8, wherein the fluoride salt includes at least one of NH₄HF₂, NaF, and KF.

14. The method of claim 13, wherein the fluoride salt is molten and is about 0.001 weight percent through about 2 weight percent in the low-polarity organic solvent.

15. The method of claim 1, wherein the layer is silicon oxide layer.

16. The method of claim 2, wherein drying the dummy contact hole includes one of spinning the substrate and supplying one of air and N₂ gas to the substrate.

17. The method of claim 16, wherein the substrate is spun at 2000 rotations per minute.

18. The method of claim 9, wherein drying the dummy contact hole includes one of spinning the substrate and supplying one of air and N₂ gas to the substrate.

19. The method of claim 18, wherein the substrate is spun at 2000 rotations per minute.
